(19) United States
(12) Patent Application Publication
(10) Pub. No.: US 2026/0075962 A1
(43) Pub. Date: Mar. 12, 2026

(54) DUAL-DIODE FAIL-SAFE INPUT/OUTPUT (FSIO) SCHEME AS ELECTROSTATIC DISCHARGE (ESD) FSIO SOLUTION

(71) Applicant: TAIWAN SEMICONDUCTOR MANUFACTURING COMPANY LTD., HSINCHU (TW)

(72) Inventors: HSIN-YUAN YU, HSINCHU COUNTY (TW); LI-WEI CHU, HSINCHU CITY (TW); CHIA-HUI CHEN, HSINCHU (TW); WUN-JIE LIN, HSINCHU CITY (TW)

(21) Appl. No.: 19/032,139

(22) Filed: Jan. 20, 2025

Related U.S. Application Data
(60) Provisional application No. 63/691,346, filed on Sep. 6, 2024.

(51) Int. Cl. H10D 89/60

(52) U.S. Cl. CPC H10D 89/921; H10D 89/713; H10D 89/819

(57) ABSTRACT

A semiconductor device is provided, including an input/output (I/O) pad, a power clamp, an electrostatic discharge (ESD) clamp circuit, a bias circuit, and a voltage-triggered source. The power clamp is coupled between first and second power rails. The ESD clamp circuit is connected to the I/O pad and coupled between an electrostatic discharge bus and the second power rail. The bias circuit is coupled between the first power rail and the electrostatic discharge bus, and is configured to couple the ESD bus to the first power rail during a normal operation mode, and float the electrostatic discharge bus during an electrostatic discharge mode or a fail-safe mode. The voltage-triggered source is coupled between the ESD bus and the second power rail, and provides a trigger voltage for a first electrostatic discharge path in response to an ESD event occurring on the I/O pad.

### CROSS-REFERENCE TO RELATED APPLICATION(S)

This application claims the benefit of U.S. Provisional Application No. 63/691,346, filed Sep. 6, 2024, the entire disclosure of which is incorporated by reference herein.

### BACKGROUND

Electrostatic discharge (ESD) constitutes a rapid transfer of electrical charge between electrically charged entities, potentially arising from contact, electrical short circuits, dielectric breakdown, among other causes. In the absence of adequate control measures, ESD can inflict damage upon objects, such as integrated circuit, through which it traverses, and/or interfere with electrical communication signals. ESD incidents may be precipitated by static electricity, electrostatic induction, or malfunctions within internal circuitry.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features can be arbitrarily increased or reduced for clarity of discussion.

FIG. 1 is an equivalent circuit of part of a semiconductor device with fail-safe ESD protection, in accordance with some embodiments of the present disclosure.

FIG. 2 is a cross-sectional view of the ESD clamp circuit within the semiconductor device in accordance with some embodiments of the present disclosure.

FIG. 3A is a simplified equivalent circuit of part of the semiconductor device with fail-safe ESD protection, in accordance with some embodiments of the present disclosure.

FIG. 3B is a simplified equivalent circuit of part of the semiconductor device with fail-safe ESD protection, in accordance with still some embodiments of the present disclosure.

FIG. 3C is a simplified equivalent circuit of part of the semiconductor device with fail-safe ESD protection, in accordance with still some embodiments of the present disclosure.

FIG. 4 is a simplified equivalent circuit of part of the semiconductor device with fail-safe ESD protection, in accordance with still some embodiments of the present disclosure.

FIGS. 5A to 5B are circuit diagrams of the ESD bus bias circuit in FIG. 4.

FIG. 6 is a simplified equivalent circuit of part of the semiconductor device with fail-safe ESD protection, in accordance with still some embodiments of the present disclosure.

FIG. 7 is a top view of a layout of the semiconductor device in accordance with some embodiments of the present disclosure.

FIG. 8 is a flowchart of a method for operating an integrated circuit with ESD protection in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, it will be understood that when an element is referred to as being “connected to” or “coupled to” another element, it can be directly connected to or coupled to the other element, or intervening elements can be present.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device can be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

A clamp circuit as commonly used in ESD protection devices can be referred to as an “ESD power-rail clamp circuit” or “ESD clamp circuit.” The clamp circuit may include an ESD detection circuit and a discharge device. In general, a discharge device can include relatively large transistors, with commensurately large scale in terms of channel width. A transistor of large channel width can be referred to as a “BigFET.” The term “BigFET” can refer to an N-type or P-type transistor having channel width equaling or exceeding 1000 μm.

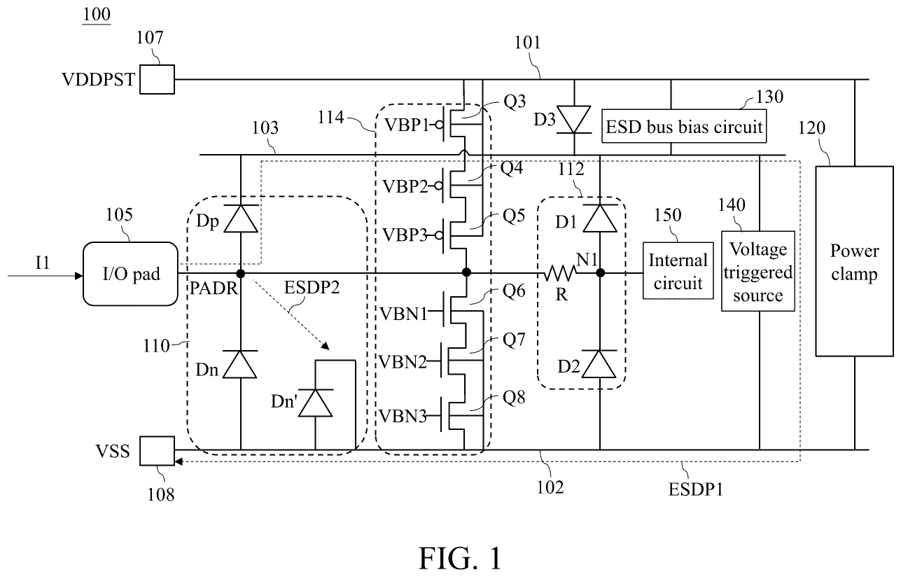

FIG. 1 is an equivalent circuit of part of a semiconductor device with fail-safe ESD protection, in accordance with some embodiments of the present disclosure.

In some embodiments, the semiconductor device 100 includes an input/output (I/O) pad 105, electrostatic discharge (ESD) clamp circuits 110 and 112, a driver circuit 114, a voltage trigger source 140, a power clamp 120, an ESD bus bias circuit 130, and an internal circuit 150, as depicted in FIG. 1. The power clamp 120 is coupled between power rails 101 and 102, which receive a power supply voltage VDDPST and a reference voltage VSS through terminals 107 and 108, respectively. The power clamp 120 is configured to clamp a voltage between the power rails 101 and 102. The ESD clamp circuits 110 and 112 are coupled between an ESD bus 103 and power rail 102, and are configured to discharge electric charges to the ground (e.g., terminal 108 for the reference voltage VSS) along one or more discharge paths in response to the occurrence of an ESD event on the I/O pad 105. The ESD bus 103 can also be regarded as an ESD floating rail, which is coupled to the power supply voltage VDDPST (or VDD) during the normal operation mode of the semiconductor device 100, and is controlled as floating during an ESD event on the I/O pad 105 in an ESD mode (e.g., all DC bias voltages and power supply voltages are not provided) of the semiconductor device 100 or in a fail-safe input/output (FSIO) mode of the semiconductor device 100 (e.g., power supply voltage VDD or VDDPST is turned off during the normal operation mode). The one or more discharge paths may include an internal discharge path (e.g., ESDP2) within the ESD clamp circuit 110 and a discharge path through the voltage triggered source 140. The voltage triggered source 140 may function as a discharge device with a pre-designed voltage potential for activation to discharge part of the ESD current I1 along the ESD path ESDP1.

In some embodiments, the internal circuit 150 is coupled to the I/O pad 105. Although not explicitly shown in FIG. 1, the internal circuit 150 is coupled between the power rails 101 and 102. The internal circuit 150 is configured to receive signals input through the I/O pad 105 or to transmit signals output through the I/O pad 105. In some embodiments, the internal circuit 150 includes logic or circuits that are configured to process or operate in response to external signals transmitted through the I/O pad 105. In some embodiments, the driver circuit 114 includes transistors Q3 to Q8, with transistors Q3 to Q5 being driven by respective bias voltages VBPI to VBP3 and transistors Q6 to Q8 being driven by respective bias voltages VBNI to VBN3. The driver circuit 114 is configured to improve the driving capability of the input signal received by the I/O pad 105, such that the internal circuit 150 can receive input signals (e.g., at node N1) with enhanced driving capability during normal operation mode. In some embodiments, the driver circuit 114 may be omitted. It should be noted that the semiconductor device 100 may include multiple voltage domains, such as power supply voltages VDDPST (or VDD), VDDL, and VSSH. For brevity, the power supply voltages VDDL and VSSH and their associated power clamps are omitted in FIG. 1.

In some embodiments, the ESD bus bias circuit 130 and diode D3 are configured to provide a fail-safe protection of the internal circuit 150 from ESD events occurring on the I/O pad 105. For example, when an ESD event with a very high positive ESD voltage occurs on the I/O pad 105, the ESD bus bias circuit 130 and diode D3 prevent from the high positive ESD voltage being transferred to power rail 101 for the power supply voltage VDDPST, as the ESD clamp circuits 110 and 112 discharge the electric charges of the ESD event along one or more discharge paths simultaneously, thereby preventing the ESD event from damaging the internal circuit 150.

In some embodiments, the ESD clamp circuit 110 includes diodes Dp, Dn, and Dn′, which are formed by disposing N-type diffusion regions and P-type diffusion regions in N-type well regions or P-type well regions on a substrate. As depicted in FIG. 1, an anode of diode Dp is coupled to ESD bus 103, and a cathode of diode Dp is coupled to the I/O pad 105, which is equivalent to the intermediate node PADR. Additionally, an anode of diode Dn is coupled to the I/O pad 105 or the intermediate node PADR, and a cathode of diode Dn is coupled to the power rail 102, which receives the reference voltage VSS through terminal 108. An anode and a cathode of diode Dn′ are coupled to power rail 102. Furthermore, the cathode of diode Dp, intermediate node PADR (or I/O pad 105), and the anode of diode Dn are coupled to each other. The details of the configuration of the diodes Dp, Dn, and Dn′ will be discussed in the following paragraphs. However, the scope of the present disclosure is not intended to be limited to the aforementioned types, and other suitable arrangements of types of the diodes Dp, Dn, and Dn′ are within the contemplated scope of the present disclosure.

In some embodiments, the ESD clamp circuit 112 includes diodes D1 and D2, which are formed by disposing N-type diffusion regions and P-type diffusion regions in N-type well regions or P-type well regions on a substrate. As depicted in FIG. 1, the input terminal (e.g., node N1) of the internal circuit is electrically connected to the I/O pad 105 through the resistance R, which represents the resistance contributed by the metal routing arranged to couple the ESD clamp circuit 112 and the internal circuit 150 with the I/O pad 105 or other corresponding elements. In some embodiments, the resistance R is omitted, thereby not affecting operations of circuits in the semiconductor device 100.

During an electrostatic discharge (ESD) event, there is an instantaneous buildup of a substantial electrical positive potential at the I/O pad 105, which is generally caused by direct or indirect contact with an electrostatic field. As the ESD event occurs, multiple ESD paths, including, for example, ESDP1 and ESDP2 as shown in FIG. 1, are conducted in the semiconductor device 100, allowing the ESD current I1 to be discharged. Specifically, as shown in FIG. 1, one part of the ESD charge current I1 flows from the I/O pad 105 to terminal 108 along the ESD path ESDP1 through diode Dp, ESD bus 103, the voltage trigger source 140, and power rail 102. Another part of the ESD charge current I1 flows from the I/O pad 105 to terminal 108 along the ESD path ESDP2 in which a semiconductor structure included in the diode Dp and the diode Dn′ discharges part of the ESD current I1. Details of the semiconductor structure included in the diode Dp and the diode Dn′ are discussed below.

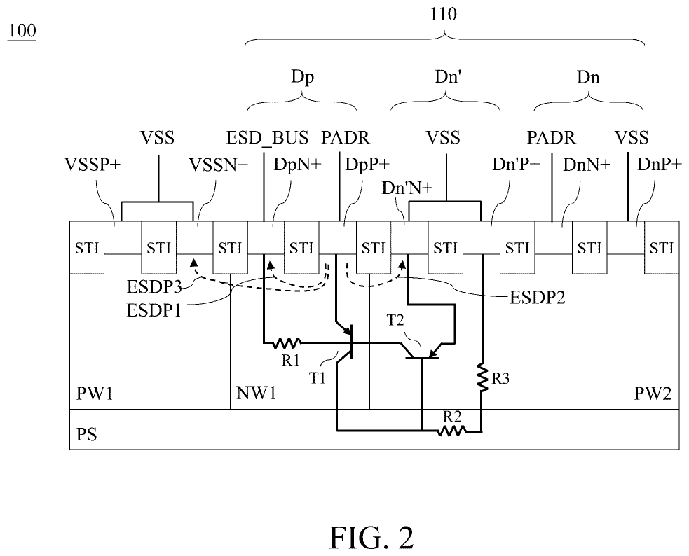

To further understand the structure of part of the semiconductor device 100 shown in the embodiments in FIG. 1, reference is now made to FIG. 2, which is a cross-sectional view of the ESD clamp circuit 110 within the semiconductor device 100 in accordance with some embodiments of the present disclosure.

As depicted in FIG. 2, the semiconductor device 100 includes a P-well PW1, an N-well NW1, and a P-well PW2 that are disposed on a P-type substrate PS. The metal wires electrically connected to the P+ doped region DpP+ and the N+ doped region DnN+ are for connecting the regions DpP+, DnN+, and the I/O pad 105. Additionally, the metal wire electrically connected to the N+ doped region DpN+ is for connecting the region DpN+ and the ESD bus 103. Moreover, the metal wires electrically connected to the N+ doped regions Dn′N+ and VSSN+, and P+ doped regions Dn′P+, DnP+, and VSSP+ are for connecting the regions DnN+, DnP+, DnP+, DnN+, VSSN+, VSSP+, and power rail 102 for the reference voltage VSS.

In some embodiments, the N+ doped regions VSSN+, DpN+, Dn′N+, DnN+ refer to regions doped with n-type dopants, such as phosphorus, arsenic, or a combination thereof. The P+ doped regions VSSP+, DpP+, Dn′ P+, DnP+ refer to regions doped with p-type dopants, such as boron, indium, aluminum, gallium, or a combination thereof. In some embodiments, the P-wells disclosed herein are formed by doping a substrate with p-type dopants, unless mentioned otherwise. Similarly, the N-wells disclosed herein are formed by doping a substrate with n-type dopants, unless mentioned otherwise. In some embodiments, the P-type substrate PS includes a semiconductor material such as, but not limited to, silicon, germanium, a compound semiconductor including silicon carbide, and gallium arsenide, doped with p-type dopants. In some embodiments, the shallow trench isolations SI are formed by creating trenches in the N-well NW1 and the P-wells PW1 and PW2, and filling the trenches with a dielectric material, including, for example, silicon dioxide, a high-density plasma (HDP) oxide, or the like. Furthermore, the semiconductor device 100 includes shallow trench isolations STI for separating the N+ doped regions VSSN+, DpN+, Dn′N+, DnN+, and P+ doped regions VSSP+, DpP+, Dn′ P+, DnP+, as depicted in FIG. 2.

In some embodiments, diode Dp includes regions DpP+ and DpN+ formed within the N-well NW1. The region DpP+ is configured to function as the anode of diode Dp and configured to be coupled to the ESD bus 103 (e.g., ESD_BUS), while the region DpN+ is configured to function as the cathode of diode Dp and configured to be coupled to the I/O pad 105 (or the intermediate node PADR). Additionally, diode Dn′ includes regions Dn′P+ and Dn′N+ formed within the P-well PW2 adjacent to the N-well NW1. The region Dn′P+ is configured to function as the anode of diode Dn′, while the region Dn′N+ is configured to function as the cathode of diode Dn′. The regions Dn′P+ and Dn′N+ are configured to be coupled to power rail 102 for the reference voltage VSS. Furthermore, diode Dn includes regions DnP+ and DnN+ formed within the P-well PW2. The region DnP+ is configured to function as the anode of diode Dn and configured to be coupled to power rail 102 for the reference voltage VSS, while the region DnN+ is configured to function as the cathode of diode Dn and is configured to be coupled to the I/O pad 105 (or the intermediate node PADR).

Referring to FIG. 2, a parasitic PNP transistor T1, a parasitic NPN transistor T2, and parasitic resistances R1, R2, and R3 are formed and coupled within the semiconductor structure of the semiconductor device 100. In some embodiments, the parasitic PNP transistor T1, the parasitic NPN transistor T2, and the parasitic resistances R1, R2 and R3 operate together as an equivalent silicon-controlled rectifier (SCR) circuit. The equivalent SCR circuit shown in FIG. 2 is given for illustrative purposes. Various equivalent SCR circuits are within the contemplated scope of the present disclosure. For example, in various embodiments, at least one of the parasitic resistance R1, R2, or R3 is omitted. Additionally, the ESD clamp circuit 110 formed by diodes Dp, Dn, and Dn′ can be regarded as a dual-diode silicon-controlled rectified (DDSCR) coupled between the ESD bus 103 and power rail 102 for the reference voltage VSS.

In some embodiments, the parasitic PNP transistor T1 includes the region DpP+ as an emitter, the N-well NW1 as a base, and the P-type substrate PS as a collector. The base of the PNP transistor T1 is coupled to the region DpN+ through the parasitic resistance R1, which represents the intrinsic resistance of the N-well NW1. The collector of the parasitic PNP transistor T1 is coupled to the region Dn′P+ through parasitic resistances R2 and R3, where the parasitic resistance R2 represents the intrinsic resistance of the P-type substrate PS, and the parasitic resistance R3 represents the intrinsic resistance of the P-well PW2. The parasitic NPN transistor T2 includes the N-well NW1 as a collector, the P-well PW2 as a base, and the region Dn′N+ as an emitter. The collector of the parasitic NPN transistor T2 is coupled to the base of the parasitic PNP transistor T1. The base of the parasitic NPN transistor T2 is coupled to the region Dn′P+ through the parasitic resistances R2 and R3. The emitter of the parasitic NPN transistor T2 is coupled to the region Dn′N+.

In some embodiments, the semiconductor structure included in the diode Dp and diode Dn′ is configured as the ESD path ESDP2 (also as shown in FIG. 1), and is designed to operate as the equivalent silicon-controlled rectifier (SCR) circuit (e.g., P-N-P-N junctions) as discussed above. Alternatively stated, the region DpP+ of the diode Dp, the N-well NW1, the P-type substrate PS, the P-well PW2 and the regions Dn′N+ and Dn′P+ of the diode Dn′ are configured to operate as the SCR circuit. For example, in some embodiments, a portion of the ESD current I1 injected from the I/O pad 105 flows through the region DpP+, the N-well NW1, the P-type substrate PS, the P-well PW2, and the regions Dn′N+ and Dn′P+ of the diode Dn′ to terminal 108 for the reference voltage VSS. It should be noted that the ESD path ESDP2 is not activated until the ESD path ESDP1 is activated during the ESD mode, indicating that the voltage triggered source 140 is activated in response to the high ESD voltage of an ESD event occurring on the I/O pad 105.

When the semiconductor device 100 is in the fail-safe mode with the power supply voltage VDDPST being turned off, during an ESD event with a high positive ESD voltage, the diode Dp and the voltage triggered source 140 shown in FIG. 1 are turned on to further trigger the SCR circuit shown in FIG. 2. At least part of the ESD current I1 flows from the I/O pad 105, through the ESD path ESDP1 of FIG. 1 including the region DpP+ of the diode Dp, the N-well NW1, and the region DpN+ of the diode Dp, to the terminal 107 for the power supply voltage VDDPST. Moreover, the parasitic transistor T1 and the parasitic transistor T2 are turned on during the fail-safe mode. Thus, another part of the ESD current I1 flows from the I/O pad 105, through the ESD path ESDP2 including the parasitic transistor T1 (corresponding to the region DpP+ of the diode Dp, the N-well NW1, the P-type substrate PS), the parasitic resistance R2 (corresponding to the P-type substrate PS), the parasitic transistor T2 (corresponding to the N-well NW1, the P-well PW2, and the region Dn′N+) and the parasitic resistance R3, to terminal 108 for the reference voltage VSS. With the configuration illustrated in FIG. 1 and FIG. 2, in addition to the ESD path ESDP1, a part of the ESD current I1 is further shunted to ground through the ESD path ESDP2.

In some embodiments, the semiconductor device 100 further includes regions VSSP+ and VSSN+ formed in the P-well PW1, as shown in FIG. 2. For illustration, the region VSSN+ is doped with n-type dopants as discussed above. With the semiconductor structure including the region VSSN+ within the P-well PW1, an ESD path ESDP3 is also conducted in some embodiments. In various embodiments, the ESD path ESDP3 is also implemented with another equivalent SCR circuit which, for simplicity of illustration, is not shown in FIG. 2. The other part of the ESD current I1 flows from the I/O pad 105 through the ESD path ESDP3, including the region DpP+ of the diode Dp, and the region VSSN+ to the terminal 108 for the reference voltage VSS.

It should be noted that the configurations shown in FIG. 2 are given for illustrative purposes. Various configurations of the elements mentioned above in FIG. 2 are within the contemplated scope of the present disclosure. For example, in various embodiments, the semiconductor structure including the P-well PW1 and the regions VSSP+ and VSSN+ can be omitted.

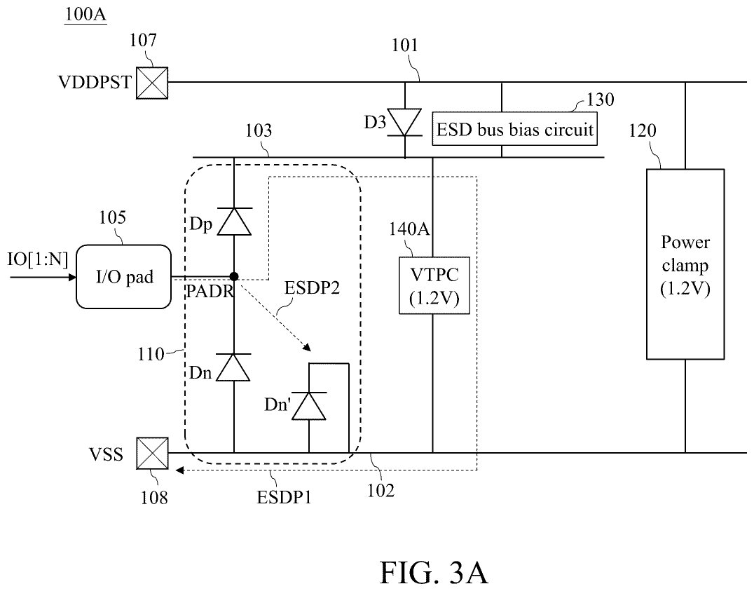

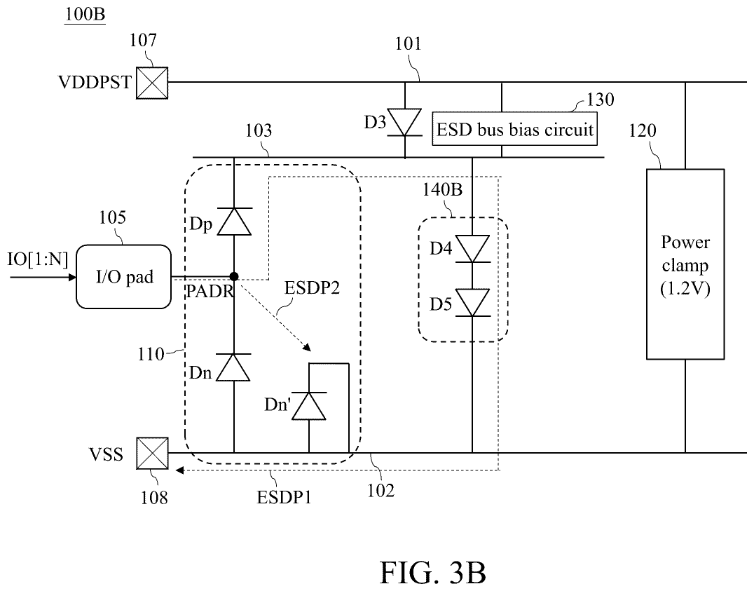

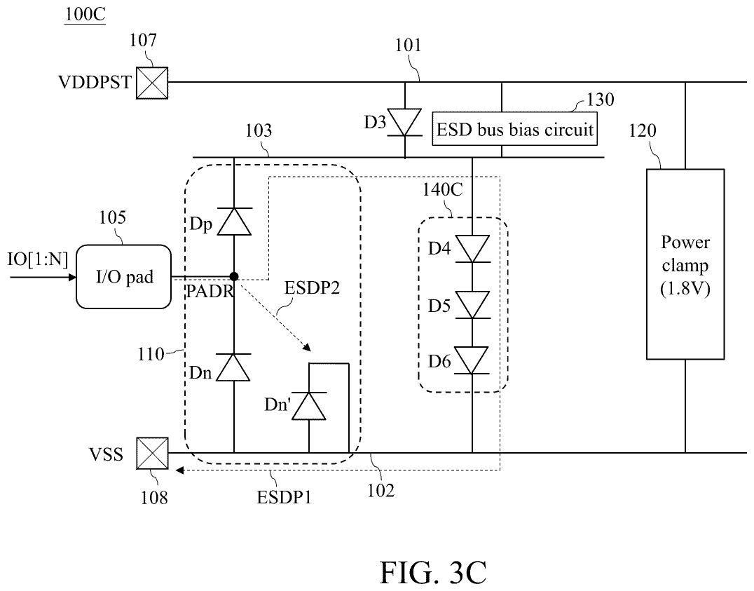

FIG. 3A is a simplified equivalent circuit of part of the semiconductor device with fail-safe ESD protection, in accordance with some embodiments of the present disclosure.

For purposes of description, the driver circuit 114, ESD clamp circuit 112, and internal circuit 150 within the semiconductor device 100 shown in FIG. 1 are omitted from the semiconductor device 100A shown in FIG. 3A. Generally, self protection pull down devices (e.g., such as snapback NMOS transistors) are required for electrostatic discharge (ESD) networks to form a path where ESD current may be discharged, for example. However, snapback NMOS devices require a drain extension (e.g., such that a drain region for the snapback NMOS device is larger than a drain region for a non-snapback NMOS device). In some embodiments, the semiconductor device 100 shown in FIG. 1 may operate in a fail-safe input/output (FSIO) mode with a power supply voltage VDDPST of 1.2V or 1.8V, such as for a technology node of 2 nm (e.g., N2 technology) which lacks a snapback NMOS transistor with a drain extension for ESD protection.

For example, the semiconductor device 100A shown in FIG. 3A operates in the 1.2V FSIO mode (e.g., VDDPST=1.2V), with the voltage triggered source 140 being implemented using a voltage-triggered power clamp (VTPC) 140A with a trigger voltage of 1.2V, which is equal to the power supply voltage VDDPST. Additionally, the power clamp 120, coupled between power rails 101 and 102, may be a resistance-capacitance (RC) power clamp with a trigger voltage of 1.2V. In some embodiments, although not explicitly shown in FIG. 3A, the VTPC 140A may include a BigFET, such as a N-type or P-type transistor having a relatively large channel width than other transistors within the semiconductor device 100A, which functions as a discharge device for discharging electric charges of an ESD event occurring on the I/O pad 105. Specifically, the ESD clamp circuit 110, including diodes Dp, Dn, and Dn′, can operate in conjunction with the VTPC 140A to significantly suppress the transient current during the 1.2V FSIO mode, i.e., when the power supply voltage VDDPST is turned off.

Additionally, the BigFET within the VTPC 140A can dominate the direct-current (DC) leakage current of the semiconductor device 100A. With the design of semiconductor device 100A, the channel width (or transistor width) of the BigFET within the VTPC 140A can be reduced to meet the requirements for the DC leakage current of the semiconductor device 100A.

When an ESD event with a high ESD voltage (i.e., greater than approximately 2.2V which is the sum of the estimated threshold voltage of diode Dp and the trigger voltage of the VTPC 140A) occurs on the I/O pad 105, diode Dp and the VTPC 140A are activated, enabling the ESD path ESDP1 from the I/O pad 105 to terminal 108 through diode Dp and VTPC 140A. Furthermore, since the diode Dp is activated, the SCR (e.g., diode Dn′) within the ESD clamp circuit 110 is also turned on, enabling the ESD path ESDP2 from the I/O pad 105 (or the intermediate node PADR) to terminal 108 through the SCR (e.g., diode Dn′).

FIG. 3B is a simplified equivalent circuit of part of the semiconductor device with fail-safe ESD protection, in accordance with still some embodiments of the present disclosure.

In some embodiments, the semiconductor device 100B shown in FIG. 3B operates in the 1.2V FSIO mode (e.g., VDDPST=1.2V), with the voltage triggered source 140 being implemented using a diode string 140B, which includes diodes D4 and D5. The diodes D4 and D5 may be implemented using P-type transistors in a diode-connected configuration (e.g., the P-type transistor has a gate connected to its source), and each diode D4 and D5 may have a threshold voltage of approximately 0.6V. Accordingly, the diode string 140B may have a trigger voltage of approximately 1.2V, which is equal to the power supply voltage VDDPST. Additionally, the power clamp 120, coupled between power rails 101 and 102, may be a resistance-capacitance (RC) power clamp with a trigger voltage of 1.2V. It should be noted that the diode string 140B shown in FIG. 3B may have a smaller area compared to the VTPC 140A shown in FIG. 3A, allowing the semiconductor device 100B to achieve a better PPA (power, performance, and area).

When an ESD event with a high ESD voltage (i.e., relatively larger than 3V, which is approximately 3 times the estimated threshold voltage of diodes Dp, D4 and D5) occurs on the I/O pad 105, diode Dp and the diode string 140B are activated, enabling the ESD path ESDP1 from the I/O pad 105 to terminal 108 through diode Dp and diode string 140B. Furthermore, since diode Dp is activated, the SCR (e.g., diode Dn′) within the ESD clamp circuit 110 is also activated, enabling the ESD path ESDP2 from the I/O pad 105 (or the intermediate node PADR) to terminal 108 through the SCR (e.g., diode Dn′).

FIG. 3C is a simplified equivalent circuit of part of the semiconductor device with fail-safe ESD protection, in accordance with still some embodiments of the present disclosure.

In some embodiments, the semiconductor device 100B shown in FIG. 3C operates in the 1.8V FSIO mode (e.g., VDDPST=1.8V), with the voltage triggered source 140 being implemented using a diode string 140C, which includes diodes D4, D5, and D6. The diodes D4, D5, and D6 may be implemented using P-type transistors in a diode-connected configuration (e.g., the P-type transistor has a gate connected to its source), and each diode D4 to D6 may have a threshold voltage of approximately 0.6V. Accordingly, the diode string 140C may have a trigger voltage of approximately 1.8V, which is equal to the power supply voltage VDDPST. Additionally, the power clamp 120, coupled between power rails 101 and 102, may be a resistance-capacitance (RC) power clamp with a trigger voltage of 1.8V.

When an ESD event with a high ESD voltage (i.e., relatively larger than 4V, which is approximately 4 times the estimated threshold voltage of diodes Dp, D4, D5, and D6) occurs on the I/O pad 105, diode Dp and the diode string 140C are activated, enabling the ESD path ESDP1 from the I/O pad 105 to terminal 108 through diode Dp and diode string 140C. Furthermore, since diode Dp is activated, the SCR (e.g., diode Dn′) within the ESD clamp circuit 110 is also activated, enabling the ESD path ESDP2 from the I/O pad 105 (or the intermediate node PADR) to terminal 108 through the SCR (e.g., diode Dn′).

In some embodiments, in response to an ESD event with a high positive ESD voltage occurring on the I/O pad 105, the voltage-trigger sources, including VTPC 140A and diode strings 140B and 140C, shown in FIGS. 3A to 3C may have a low transient current before the DDSCR (e.g., ESD clamp circuit 110) is activated, providing a promising ESD window. Additionally, the DDSCR (e.g., ESD clamp circuit 110) within the FSIO network of the semiconductor device 100 functions as a local ESD clamp with a reduced clamp voltage, saving more immunity margin for the internal circuit 150 (e.g., victim circuit) between the I/O pad 105 and power rails 101 and 102 (i.e., for VDDPST/VSS).

In some embodiments, the combination of the DDSCR with the VTPC or the diode string in the ESD FSIO network within the semiconductor device 100 can provide an enhanced PPA with reduced area and power, and maintains a stable low leakage current under the ESD floating rail structure. Additionally, the combination of the DDSCR with the VTPC or the diode string in the ESD FSIO network can be integrated into the GPIO (general-purpose input/output) design with slight modifications. Furthermore, the design of the ESD bus bias circuit can stabilize the ESD rail during the FSIO mode when the power supply voltage VDDPST is turned off and the input signal to the I/O pad 105 is toggled normally (e.g., from 0 to 1.35V at 1.2V FSIO mode) at a high frequency, thereby achieving more stable timing performance.

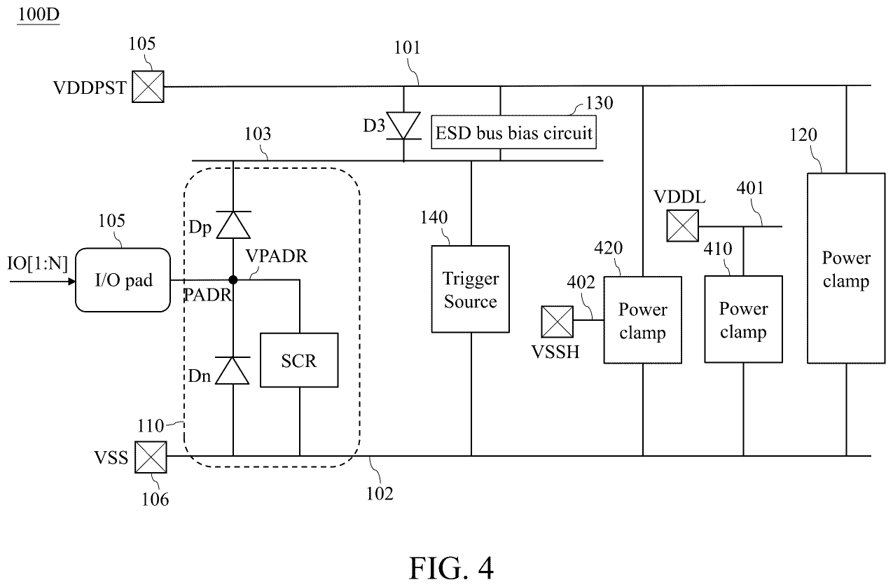

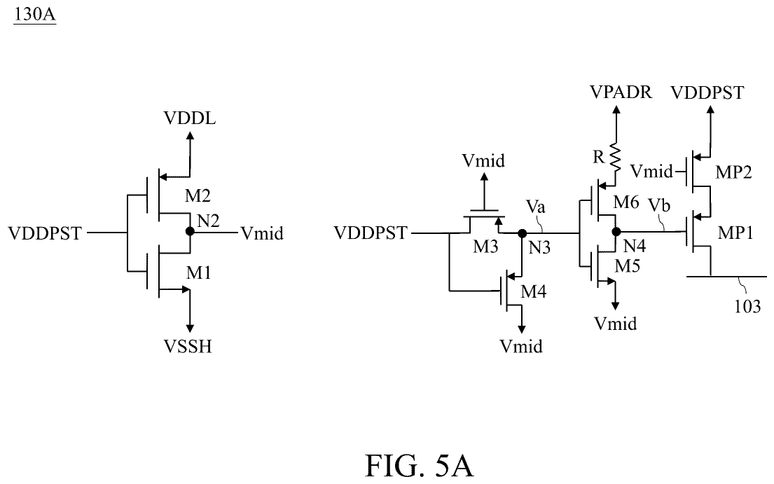

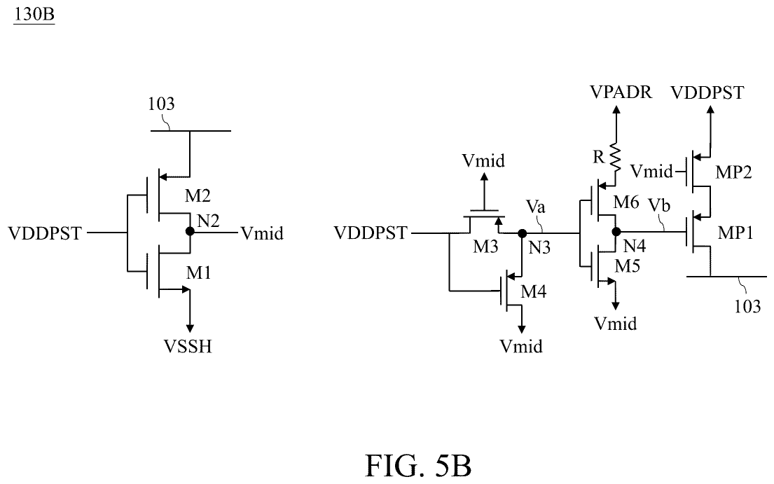

FIG. 4 is a simplified equivalent circuit of part of the semiconductor device with fail-safe ESD protection, in accordance with still some embodiments of the present disclosure. FIGS. 5A to 5B are circuit diagrams of the ESD bus bias circuit in FIG. 4.

The semiconductor device 100 shown in FIG. 1 may be implemented using the semiconductor device 100D shown in FIG. 4. In some embodiments, the semiconductor device 100D may include multiple voltage domains, such as power supply voltages VDDPST, VDDL, and VSSH, which can be regarded as a post-driver power supply voltage, a low-side logic power supply voltage, and a high-side logic ground voltage, respectively. The power clamp 120 is coupled between power rails 101 and 102 for the power supply voltage VDDPST and the reference voltage VSS, respectively. The power clamp 410 is coupled between power rails 401 and 102 for the power supply voltage VDDL and the reference voltage VSS, respectively. The power clamp 420 is a combo power clamp coupled between power rails 101, 402, and 102 for the power supply voltages VDDPST and VSSH, and the reference voltage VSS, respectively. In some embodiments, the power supply voltages VDDPST, VDDL, and VSSH may be approximately 1.2V, 0.8V, and 0.4V, respectively, but the present disclosure is not limited thereto.

In some embodiments, the ESD bus bias circuit 130 is configured to bias the ESD bus 103 to the power supply voltage VDDPST during the normal operation mode of the semiconductor device 100D, thereby providing stable I/O timing and leakage performance. Additionally, the ESD bus bias circuit 130 is further configured to float the ESD bus 103 during the fail-safe mode (e.g., VDDPST is turned off), thereby avoiding a leakage current from the I/O pad 105 to power rail 101 for the power supply voltage VDDPST. In some embodiments, a variety of voltages, such as VDDPST, VDDL, VSSH, Vmid, VPADR, are used by the ESD bus bias circuit 130, the details of which are described as follows with reference to FIGS. 5A and 5B.

In some embodiments, the ESD bus bias circuit 130 shown in FIG. 4 may be implemented using the ESD bus bias circuit 130A shown in FIG. 5A. Referring to FIG. 5A, the ESD bus bias circuit 130A includes transistors M1 to M6 and MP1 to MP2. For example, a voltage converter is formed by transistor M1 and M2, which is supplied with the power supply voltages VSSH and VDDL, respectively. The power supply voltage VDDPST is provided to the gate terminals of transistors M1 and M2, thereby converting the power supply voltage VDDPST to an intermediate voltage Vmid, which is between the power supply voltages VSSH and VDDL, at an output terminal (e.g., node N2) of the voltage converter during the normal operation mode or the fail-safe mode.

In some embodiments, the voltage levels of different voltages used by the ESD bus bias circuit 130A during the normal operation mode or the fail-safe (FS) mode with different voltages at the I/O pad (PAD) 105 are illustrated in Table 1 as follows.

TABLE 1

| | VDDPST | VDDL | VSSH | Vmid | Va | Vb | ESD_BUS |
|---|---|---|---|---|---|---|---|
| Normal operation | 1 | 1 | 1 | VSSH | VDDPST | Vmid | VDDPST |
| mode (PAD = 0/1) | | | | | | | |
| FS mode | 0 | 1 | 0 | VDDL | Vmid | Vmid | Floating |
| (PAD = 0) | | | | | | | |
| FS mode | 0 | 1 | 0 | VDDL | Vmid | VPADR | Floating |
| (PAD = 1) | | | | | | | |

Referring to Table 1, the numeric values in the columns of VDDPST, VDDL, and VSSH refer to their respective logic states, where “1” and “0” represent the high logic state and low logic state, respectively. For example, during the normal operation mode, the power supply voltages VDDPST, VDDL, and VSSH are provided to the semiconductor device 100D, indicating that the logic states of these power supply voltages are all “1”. At this time, since the power supply voltage VDDPST is higher than the power supply voltage VSSH, transistor M1 is activated, pulling down the intermediate voltage Vmid to the power supply voltage VSSH. Additionally, transistor M3 is activated due to a lower voltage level of the intermediate voltage Vmid, while transistor M4 is deactivated due to a high voltage level of the power supply voltage VDDPST. Accordingly, the power supply voltage VDDPST is transmitted to node N2 through transistor M3, indicating that the voltage Va equals the power supply voltage VDDPST. At this time, transistor M5 is activated and transistor M6 is deactivated due to the high voltage level of the voltage Va, pulling down the voltage Vb at node N3 to the intermediate voltage Vmid. Meanwhile, the intermediate voltage Vmid is provided to the gate terminals of transistors MP1 and MP2, turning on transistors MP1 and MP2. This allows the power supply voltage VDDPST to be coupled to the ESD bus 103 through transistors MP1 and MP2. It should be noted that variations of the logic level 1 or 0 on the I/O pad 105 do not affect the aforementioned operations of transistors within the ESD bus bias circuit 130A during the normal operation mode of the semiconductor device 100D.

In some cases, during the fail-safe mode when the logic state at the I/O pad 105 is “0” (e.g., PAD=“0” or VPADR=0V), the power supply voltages VDDPST and VSSH are powered off, while the power supply voltage VDDL is powered on for I/O reliability concern. Transistor M2 is turned on due to the low voltage level of the power supply voltage VDDPST, pulling up the voltage Vmid at node N2 to the power supply voltage VDDL, which is a low-side power supply voltage. Accordingly, transistor M3 is turned off due to the high voltage level of the intermediate voltage Vmid, and transistor M4 is turned on due to the low voltage level of the power supply voltage VDDPST, pulling down the voltage Va at node N3 to the intermediate voltage Vmid. The high voltage level of the voltage Va turns off transistor M6 (e.g., with VPADR=0V) and turns on transistor M5, pulling down the voltage Vb at node N4 to the intermediate voltage Vmid. Consequently, the high voltage level of the intermediate voltage Vmid is provided to the gate terminals of transistor MP1 and MP2, turning off transistors MP1 and MP2, and resulting in the ESD bus 103 being floating.

Additionally, during the fail-safe mode when the logic state at the I/O pad 105 is “1” (e.g., PAD=“1” or VPADR=VDDPST), the power supply voltages VDDPST and VSSH are powered off or fail, while the power supply voltage VDDL is powered on for I/O reliability concern. Transistor M2 is turned on due to the low voltage level of the power supply voltage VDDPST, pulling up the voltage Vmid at node N2 to the power supply voltage VDDL, which is a low-side power supply voltage. Accordingly, transistor M3 is turned off due to the high voltage level of the intermediate voltage Vmid, and transistor M4 is turned on due to the low voltage level of the power supply voltage VDDPST, pulling down the voltage Va at node N3 to the intermediate voltage Vmid. The high voltage level of the voltage Va turns off transistor M6 (e.g., with VPADR=VDDPST) and turns on transistor M5, pulling down the voltage Vb at node N4 to the intermediate voltage Vmid. Consequently, the high voltage level of the intermediate voltage Vmid is provided to the gate terminals of transistor MP1 and MP2, turning off transistors MP1 and MP2, and resulting in the ESD bus 103 being floating.

Therefore, the ESD bus bias circuit 130A shown in FIG. 5A is capable of biasing the ESD bus 103 to the power supply voltage VDDPST during the normal operation mode of the semiconductor device 100D, and maintaining the ESD bus 103 floating under the fail-safe mode (i.e., regardless of the voltage level of the I/O pad 105), thereby avoiding the leakage current from the I/O pad 105 to power rail 101 for the power supply voltage VDDPST under the fail-safe mode.

Referring to FIG. 5B, in still some embodiments, the voltage levels of different voltages used by the ESD bus bias circuit 130B during the normal operation mode or the fail-safe (FS) mode with different voltages at the I/O pad (PAD) 105 are illustrated in Table 2 as follows.

TABLE 2

| | VDDPST | VDDL | VSSH | Vmid | Va | Vb | ESD_BUS |
|---|---|---|---|---|---|---|---|
| Normal operation | 1 | 1 | 1 | VSSH | VDDPST | Vmid | VDDPST |
| mode (PAD = 0/1) | | | | | | | |
| FS mode | 0 | 1 | 0 | ESD_BUS | Vmid | Floating | Floating |
| (PAD = 0) | | | | | | | |
| FS mode | 0 | 1 | 0 | ESD_BUS | Vmid | VPADR | Floating |
| (PAD = 1) | | | | | | | |

Referring to Table 2, the numeric values in the columns of VDDPST, VDDL, and VSSH refer to their respective logic states, where “1” and “0” represent the high logic state and low logic state, respectively. The operations of the transistors within the ESD bus bias circuit 130B shown in FIG. 5B during the normal operation mode is similar to those within the ESD bus bias circuit 130A shown in FIG. 5A, and thus the details thereof are not repeated here. In some cases, during the fail-safe mode when the logic state at the I/O pad 105 is “0” (e.g., PAD=“0” or VPADR=0V), the power supply voltages VDDPST and VSSH are powered off, while the power supply voltage VDDL is also powered off for power saving. Transistor M2 is turned on due to the low voltage level of the power supply voltage VDDPST, coupling node N2 to the ESD bus 103 through transistor M2. Thus, the voltage level of the intermediate voltage Vmid varies with that of the ESD bus 103 which is a non-deterministic voltage (i.e., floating) between 0V and the power supply voltage VDDPST. Accordingly, transistor M4 is turned on due to the low voltage level of the power supply voltage VDDPST, pulling down the voltage Va at node N3 to the intermediate voltage Vmid. Since the voltage VPADR is 0V, transistor M6 is turned off regardless of the voltage level of the voltage Va. Additionally, since both the gate voltage and source voltage of transistor M5 with a positive threshold voltage Vtn are equal to the intermediate voltage Vmid, transistor M5 is turned off, resulting in the voltage Vb at node N4 being floating, and turning off transistor MP1. Furthermore, since the power supply voltage VDDPST is 0V, transistor MP2 is turned off regardless of the voltage level of the intermediate voltage Vmid. Consequently, since transistors MP1 and MP2 are turned off, the ESD bus 103 is floating.

Additionally, during the fail-safe mode when the logic state at the I/O pad 105 is “1” (e.g., PAD=“1” or VPADR=VDDPST), the power supply voltages VDDPST and VSSH are powered off or fail, while the power supply voltage VDDL is also powered off for power saving. Transistor M2 is turned on due to the low voltage level of the power supply voltage VDDPST, coupling node N2 to the ESD bus 103 through transistor M2. Thus, the voltage level of the intermediate voltage Vmid varies with that of the ESD bus 103, which is a non-deterministic voltage (i.e., floating). Accordingly, transistor M4 is turned on due to the low voltage level of the power supply voltage VDDPST, pulling down the voltage Va at node N3 to the intermediate voltage Vmid. Since the voltage VPADR is at a high voltage level, transistor M6 is turned on, pulling up the voltage Vb at node N4 to the voltage VPADR, and turning off transistor MP1. Additionally, since both the gate voltage and source voltage of transistor M5 with a positive threshold voltage Vtn are equal to the intermediate voltage Vmid, transistor M5 is turned off. Furthermore, since the power supply voltage VDDPST is 0V, transistor MP2 is turned off regardless of the voltage level of the intermediate voltage Vmid. Consequently, since transistors MP1 and MP2 are turned off, the ESD bus 103 is floating.

Therefore, the ESD bus bias circuit 130B shown in FIG. 5B is capable of biasing the ESD bus 103 to the power supply voltage VDDPST during the normal operation mode of the semiconductor device 100D, and maintaining the ESD bus 103 floating under the fail-safe mode (i.e., regardless of the voltage level of the I/O pad 105), thereby avoiding the leakage current from the I/O pad 105 to power rail 101 for the power supply voltage VDDPST under the fail-safe mode.

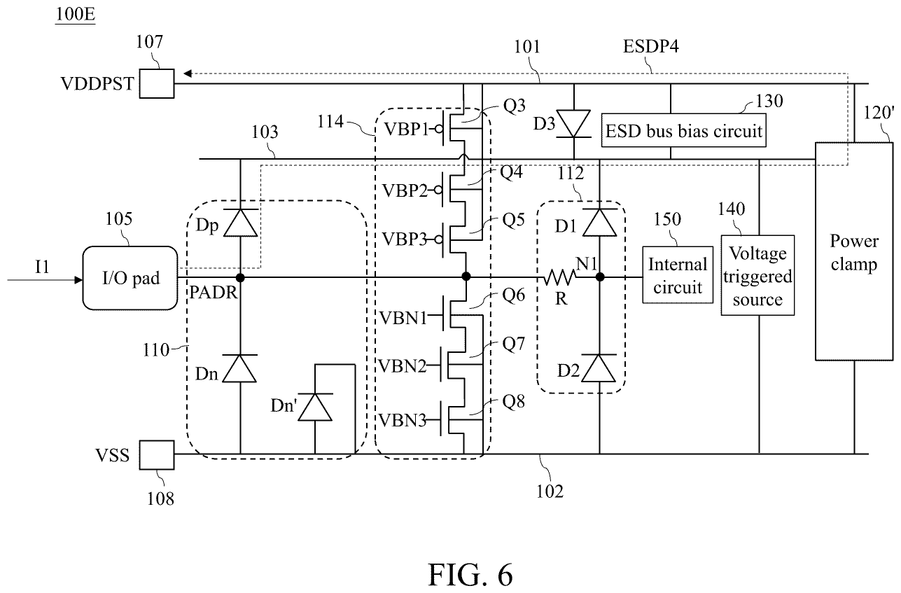

FIG. 6 is a simplified equivalent circuit of part of the semiconductor device with fail-safe ESD protection, in accordance with still some embodiments of the present disclosure.

The semiconductor device 100E shown in FIG. 6 may be similar to the semiconductor device 100 shown in FIG. 1, with the difference being that the power clamp 120′ shown in FIG. 6 is further electrically connected to the ESD bus 103 in addition to power rails 101 and 102, thereby providing an additional ESD path ESDP4, as depicted in FIG. 6. In some embodiments, the ESD bus 103 may be electrically connected to the R-C trigger circuit (not shown) within the power clamp 120′, thereby providing a discharge path from the ESD bus 103 to power rail 101 for the power supply voltage VDDPST. It should be noted that other circuit connection implementations are also applicable to the power clamp 120′, thereby providing the discharge path from ESD bus 103 to power rail 101 for the power supply voltage VDDPST.

In some embodiments, in response to an ESD event occurring on the I/O pad 105, the ESD path ESDP4 is from the I/O pad 105 to terminal 107 through diode Dp, ESD bus 103, power clamp 120′, and power rail 101, thereby discharging the electric charges of the ESD event along the ESDP4 from the I/O pad 105 to terminal 107 for the power supply voltage VDDPST.

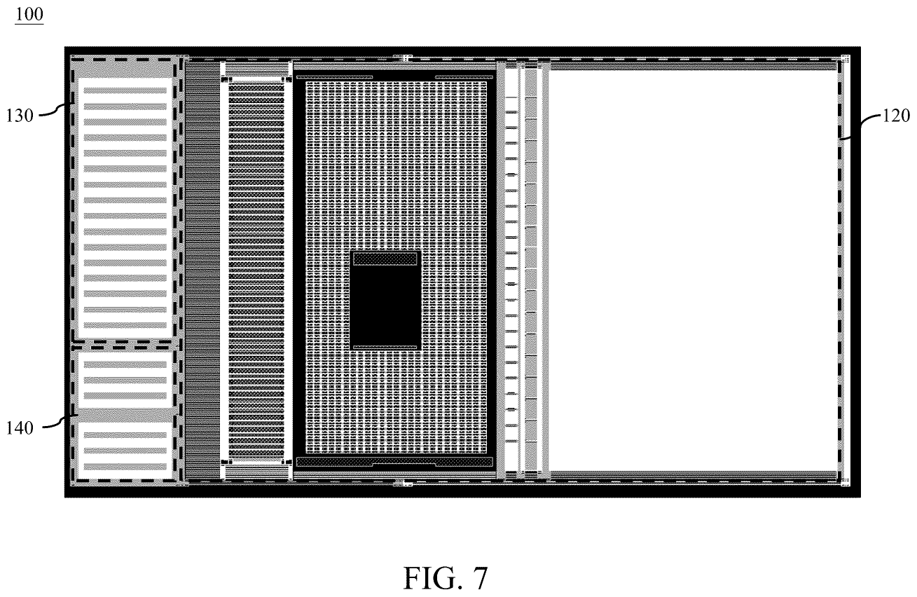

FIG. 7 is a top view of a layout of the semiconductor device in accordance with some embodiments of the present disclosure.

In some embodiments, a top view of the layout of the semiconductor device 100 in FIG. 1 is shown in FIG. 7. For brevity, the power clamp 120, ESD bus bias circuit 130, and the voltage triggered source 140 are depicted in FIG. 7. In some embodiments, the power clamp 120 occupies a relatively large area of the layout due to a large-sized discharge device (e.g., BigFET), while the voltage triggered source 140 (e.g., include a diode string of two or three diodes connected in series) occupies a relatively small area of the layout. Additionally, due to the small area of the voltage triggered source 140, the voltage triggered source 140 and the power clamp 120 can be integrated as a fixed cell layout shown in FIG. 7.

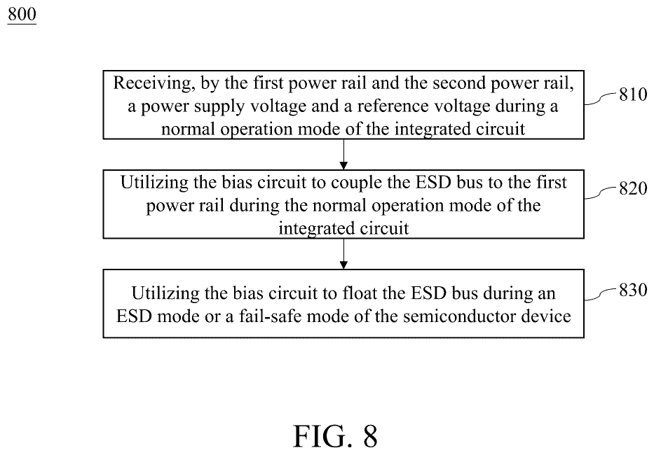

FIG. 8 is a flowchart of a method for operating an integrated circuit with ESD protection in accordance with some embodiments of the present disclosure. Please refer to FIG. 1 and FIG. 8 simultaneously. Flow 800 in FIG. 8 includes operations 810 to 840.

At operation 810, receive, by a first power rail and a second power rail, a power supply voltage VDDPST and a reference voltage VSS during a normal operation mode of an integrated circuit. In some embodiments, the ESD clamp circuit 110 is connected to the I/O pad 105 and coupled between the ESD bus 103 and the second power rail 102, while the ESD bus bias circuit 130 (e.g., the bias circuit) is coupled between the first power rail 101 and the ESD bus 103.

At operation 820, utilize the bias circuit to couple the ESD bus to the first power rail during a normal operation mode of the integrated circuit. In some embodiments, the ESD bus 103 can also be regarded as an ESD floating rail, which is coupled to the power supply voltage VDDPST (or VDD) during the normal operation mode of the semiconductor device 100.

At operation 830, utilize the bias circuit to float the ESD bus during an ESD mode or a fail-safe mode of the integrated circuit. In some embodiments, the ESD bus bias circuit 130 (e.g., the bias circuit) floats the ESD bus 103 during an ESD event on the I/O pad 105 in an ESD mode (e.g., all DC bias voltages and power supply voltages are not provided) of the semiconductor device 100 or in a fail-safe input/output (FSIO) mode of the semiconductor device 100 (e.g., power supply voltage VDD or VDDPST is turned off during the normal operation mode).

An aspect of the present disclosure provides a semiconductor device which includes an input/output pad, a power clamp, an electrostatic discharge clamp circuit, a bias circuit, and a voltage-triggered source. The input/output pad is configured to interface with external signals. The power clamp is coupled between a first power rail and a second power rail, which receive a first power supply voltage and a reference voltage, respectively. The electrostatic discharge clamp circuit is connected to the input/output pad and coupled between an electrostatic discharge bus and the second power rail. The bias circuit is coupled between the first power rail and the electrostatic discharge bus, and is configured to couple the electrostatic discharge bus to the first power rail during a normal operation mode of the semiconductor device, and float the electrostatic discharge bus during an electrostatic discharge mode or a fail-safe mode of the semiconductor device. The voltage-triggered source is coupled between the electrostatic discharge bus and the second power rail, and is configured to provide a trigger voltage for a first electrostatic discharge path in response to an electrostatic discharge event occurring on the input/output pad.

Another aspect of the present disclosure provides a semiconductor device which includes an input/output pad, a power clamp, a dual-diode silicon-controlled rectifier, a bias circuit, and a voltage-triggered source. The power clamp is coupled between a first power rail and a second power rail. The dual-diode silicon-controlled rectifier is connected to the input/output pad and coupled between an electrostatic discharge bus and the second power rail, and is configured to provide an internal electrostatic discharge path to discharge part of electric charges of an electrostatic discharge event occurring on the input/output pad. The bias circuit is coupled between the first power rail and the electrostatic discharge bus, and is configured to couple the electrostatic discharge bus to the first power rail receiving a first power supply voltage during a normal operation mode of the semiconductor device, and float the electrostatic discharge bus during a fail-safe mode of the semiconductor device. The voltage-triggered source is coupled between the electrostatic discharge bus and the second power rail, and is configured to provide a trigger voltage for a first electrostatic discharge path to discharge part of the electric charges of the electrostatic discharge event.

Yet another aspect of the present disclosure provides a method, which includes the following steps: receiving, by a first power rail and a second power rail, a power supply voltage and a reference voltage during a normal operation mode of an integrated circuit; utilizing a bias circuit of the integrated circuit to couple an electrostatic discharge (ESD) bus to the first power rail during the normal operation mode of the integrated circuit; and utilizing the bias circuit of the integrated circuit to float the ESD bus during an ESD mode or a fail-safe mode of the integrated circuit.

The methods and features of the present disclosure have been sufficiently described in the provided examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, can be utilized according to the present disclosure.

Accordingly, the appended claims are intended to include within their scope processes, machines, manufacture, compositions of matter, means, methods or steps. In addition, each claim constitutes a separate embodiment, and the combination of various claims and embodiments are within the scope of the present disclosure.

What is claimed is:

1. A semiconductor device, comprising:
an input/output (I/O) pad;
a power clamp, coupled between a first power rail and a second power rail receiving a first power supply voltage and a reference voltage, respectively;
an electrostatic discharge (ESD) clamp circuit, connected to the I/O pad and coupled between a ESD bus and the second power rail;
a bias circuit, coupled between the first power rail and the ESD bus, and configured to couple the ESD bus to the first power rail during a normal operation mode of the semiconductor device, and float the ESD bus during an ESD mode or a fail-safe mode of the semiconductor device; and
a voltage-triggered source, coupled between the ESD bus and the second power rail, and configured to provide a trigger voltage for a first ESD path in response to an ESD event occurring on the input/output pad.

2. The semiconductor device of claim 1, further comprising: a first diode, having an anode coupled to the first power rail and a cathode coupled to the ESD bus.

3. The semiconductor device of claim 1, wherein the power clamp is a resistance-capacitance power clamp.

4. The semiconductor device of claim 1, wherein the ESD clamp circuit comprises:
a second diode, having an anode coupled to the ESD bus and a cathode coupled to the I/O pad;
a third diode, having an anode coupled to the I/O pad and a cathode coupled to the second power rail; and
a silicon-controlled rectifier, coupled between the I/O pad and the second power rail.

5. The semiconductor device of claim 4, further comprising: an N-type well and a first P-type well adjacent to the N-type well formed on a P-type substrate, wherein:
the second diode comprises a first N-type doped region and a first P-type doped region formed within the N-type well;
the third diode comprises a second N-type doped region and a second P-type doped region formed within the first P-type well;
the silicon-controlled rectifier comprises a third N-type doped region and a third P-type doped region formed within the first P-type well; and
the first N-type doped region, the first P-type doped region, the second N-type doped region, the second P-type doped region, the third N-type doped region, and the third P-type doped region are separately by a plurality of shallow trench isolations.

6. The semiconductor device of claim 5, wherein in response to the ESD event occurring on the I/O pad, electric charges of the ESD event are discharged along the first ESD path from the I/O pad to a first terminal receiving the reference voltage through the second diode, the ESD bus, the voltage triggered source, and the second power rail.

7. The semiconductor device of claim 6, wherein when the voltage triggered source on the first ESD path is activated in response to the ESD event, an internal ESD path for discharging part of the electric charges of the ESD event from the I/O pad to the second power rail is established within the ESD clamp circuit through the first P-type doped region, the N-type well, the P-type substrate, and the third N-type doped region.

8. The semiconductor device of claim 7, further comprising: a second P-type well, which is adjacent to the N-type well and opposite to the first P-type well, formed on the P-type substrate, wherein a fourth N-type doped region and a fourth P-type doped region are formed within the second P-type well and are electrically connected to the second power rail.

9. The semiconductor device of claim 8, wherein in response to the ESD event occurring on the I/O pad, a second ESD path is established to part of the electric charges of the ESD event from the I/O pad to the second power rail through the first P-type doped region, the N-type well, the second P-type well, and the fourth N-type doped region.

10. The semiconductor device of claim 1, wherein the voltage-triggered source comprises a voltage-triggered power clamp with a trigger voltage equal to the first power supply voltage.

11. The semiconductor device of claim 1, wherein the voltage-triggered source comprises a diode string with a plurality of diodes connected in series, and a trigger voltage of the diode string equals the first power supply voltage.

12. The semiconductor device of claim 11, wherein each diode within the diode string comprises a P-type transistor in a diode-connected configuration.

13. The semiconductor device of claim 1, wherein:
the semiconductor device operates within a plurality of power domains, comprising the first power supply voltage, a second power supply voltage, and a third power supply voltage; and
the first power supply voltage is higher than the second power supply voltage, and the second power supply voltage is higher than the third power supply voltage.

14. The semiconductor device of claim 13, wherein:
the first power supply voltage, the second power supply voltage, and the third power supply voltage are powered on during the normal operation mode; and
the first power supply voltage and the third power supply voltage are powered off during the fail-safe mode.

15. A semiconductor device, comprising:
an input/output (I/O) pad;
a power clamp, coupled between a first power rail and a second power rail, respectively;
a dual-diode silicon-controlled rectifier, connected to the I/O pad and coupled between an electrostatic discharge (ESD) bus and the second power rail, and configured to provide an internal ESD path to discharge part of electric charges of an ESD event occurring on the input/output pad;
a bias circuit, coupled between the first power rail and the ESD bus, and configured to couple the ESD bus to the first power rail receiving a first power supply voltage during a normal operation mode of the semiconductor device, and float the ESD bus during a fail-safe mode of the semiconductor device; and
a voltage-triggered source, coupled between the ESD bus and the second power rail, and configured to provide a trigger voltage for a first ESD path to discharge part of the electric charges of the ESD event.

16. The semiconductor device of claim 15, further comprising: a first diode, having an anode coupled to the first power rail and a cathode coupled to the ESD bus.

17. The semiconductor device of claim 16, wherein the dual-diode silicon-controlled rectifier comprises:
a second diode, having an anode coupled to the ESD bus and a cathode coupled to the I/O pad;
a third diode, having an anode coupled to the I/O pad and a cathode coupled to the second power rail; and
a silicon-controlled rectifier, coupled between the I/O pad and the second power rail.

18. A method, comprising:
receiving, by a first power rail and a second power rail, a power supply voltage and a reference voltage during a normal operation mode of an integrated circuit;
utilizing a bias circuit of the integrated circuit to couple an electrostatic discharge (ESD) bus to the first power rail during the normal operation mode of the integrated circuit; and
utilizing the bias circuit of the integrated circuit to float the ESD bus during an ESD mode or a fail-safe mode of the integrated circuit.

19. The method of claim 18, wherein the method further comprises: in response to an ESD event occurring on an input/output (I/O) pad of the integrated circuit, utilizing an ESD clamp circuit of the integrated circuit, which is coupled between the ESD bus and the second power rail, to discharge electric charges of the ESD event from the I/O pad to the second power rail.

20. The method of claim 19, wherein the integrated circuit further comprises a diode string coupled between the ESD bus and the second power rail, and the method further comprises: utilizing the diode string to provide an ESD path to discharge part of the electric charges of the ESD event.
